(19) United States
(12) Patent Application Publication
(10) Pub. No.: US 2026/0198089 A1
(43) Pub. Date: Jul. 9, 2026

(54) DISPLAY APPARATUS

(71) Applicant: LG Display Co., Ltd., Seoul (KR)

(72) Inventors: Yein HONG, Paju-si (KR); Seokhwan CHOI, Paju-si (KR); DongJin AHN, Paju-si (KR)

(73) Assignee: LG Display Co., Ltd., Seoul (KR)

(21) Appl. No.: 19/371,974

(22) Filed: Oct. 28, 2025

(30) Foreign Application Priority Data
Dec. 12, 2024 (KR) 10-2024-0184463

(51) Int. Cl. H10D 86/40; H10D 86/60

(52) U.S. Cl. CPC H10D 86/441; H10D 86/451; H10D 86/60

(57) ABSTRACT

A display apparatus is disclosed, and comprises a substrate including a display area and a non-display area, a first pad region disposed in the non-display area, and an alignment mark spaced apart from the first pad region.

### CROSS-REFERENCE TO RELATED APPLICATION

This application claims the benefit of priority of the Republic of Korea Patent Application No. 10-2024-0184463 filed on Dec. 12, 2024, which is hereby incorporated by reference in its entirety.

### BACKGROUND

### Technical Field

The present disclosure relates to a display apparatus.

### Description of the Related Art

As we enter the information age, the field of display apparatuses that visually display electrical information signals is rapidly developing, and research is continuing to develop performances such as thinning, weight reduction, and low power consumption for various display apparatuses.

Recently, various display apparatuses such as liquid crystal display apparatus (“LCD”), field emission display apparatus (“FED”), and organic light emitting display apparatus (“OLED”) are being utilized.

### BRIEF SUMMARY

The disclosure presents a display apparatus with an alignment mark which is spaced apart from a pad region of a non-display area of the display apparatus. This alignment mark may include a plurality of metal portions disposed on a substrate of the display apparatus. This configuration including the alignment mark spaced apart from the pad region enables the pad height of the pad to be reduced, which enables a thinner panel to be produced.

Because the panel can be produced thinner, interference between an integrated circuit and the panel may be reduced. The reduction in interface may reduce the propagation of cracks in the display panel of the display apparatus.

The present disclosure provides a display apparatus that can improve reliability by preventing moisture infiltration due to cracks around a driving chip and corrosion failure of a pad or wire.

The present disclosure provides a display apparatus that reduces deformation of a display panel by preventing cracks from occurring around a driving chip due to concentration of stress when mounting the driving chip on a display panel.

The present disclosure provides a display apparatus capable of preventing various types of wiring from being damaged by cracks.

The present disclosure provides a display apparatus capable of improving reliability degradation of the display apparatus due to cracks.

A display apparatus according to an embodiment of the present disclosure may include a substrate including a display area and a non-display area, a first pad region disposed in the non-display area, and an alignment mark spaced apart from the first pad region.

A display apparatus according to another embodiment of the present disclosure may include a substrate including a display area and a non-display area, a plurality of insulating layers on the substrate, a pad electrode on the substrate and including a plurality of metal patterns, and first, second, and third alignment marks disposed on the substrate and adjacent to the pad electrode, wherein the first alignment mark may include a 1-1 metal layer, a 1-2 metal layer, and a second metal layer, the 1-1 metal layer and the 1-2 metal layer may be disposed on a first insulating layer of the plurality of insulating layers, and the second metal layer may be disposed on a third insulating layer of the plurality of insulating layers.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exemplary plan view of a display apparatus according to an embodiment of the present disclosure.

FIG. 2 is an exemplary drawing showing the X area of FIG. 1.

FIG. 3 is an exemplary cross-sectional view along line A-A′ of FIG. 2.

### DETAILED DESCRIPTION

Hereinafter, some embodiments of the present disclosure will be described in detail with reference to exemplary drawings. In addition, when describing the present disclosure, if it is determined that a specific description of a related known configuration or function may obscure the gist of the present disclosure, the detailed description may be omitted. When “includes,” “has,” “consists of,” etc., are used in the present disclosure, other parts may be added unless “only” is used. When a component is expressed in the singular, it may include a case where the plural is included unless there is a special explicit description.

In addition, terms such as first, second, A, B, a, b, etc., may be used to describe components of this disclosure. These terms are only intended to distinguish the components from other components, and the nature, order, sequence, or number of the components are not limited by these terms.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In a description of the positional relationship of components, when it is described that two or more components are “connected,” “coupled” or “connected,” it should be understood that the two or more components may be directly “connected,” “coupled” or “connected,” but the two or more components and another component may be further “interposed” to be “connected,” “coupled” or “connected.” Here, the other component may be included in one or more of the two or more components that are “connected,” “coupled” or “connected” to each other.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

In the description of the temporal flow relationship related to components, operation methods, or manufacturing methods, for example, when the temporal chronological relationship or the chronological flow relationship is described as “after,” “following,” “next to,” or “before,” it can also include cases where it is not continuous, as long as “immediately” or “directly” is not used.

Meanwhile, when a numerical value or its corresponding information, e.g., level, or the like. for a component is mentioned, even if there is no separate explicit description, the numerical value or its corresponding information may be interpreted as including an error range that may occur due to various factors, e.g., process factors, internal or external impact, noise, or the like.

The present disclosure relates to a display apparatus that improves mechanical reliability in the chip on panel bonding area where cracks and stress concentration often occur. It provides a restructured alignment mark and pad configuration that reduces the overall thickness of the panel near the driver integrated circuit, thereby minimizing interference between the circuit bumps and the panel. By modifying the metal and insulating layer arrangement, the apparatus alleviates mechanical stress and prevents crack formation that can lead to moisture penetration and corrosion of conductive parts.

The disclosed structure employs a multi layer alignment mark in which first metal layers are formed on a first insulating layer, and a second metal layer is formed on a third insulating layer. This staggered configuration reduces local height differences and enhances flexibility. The pad area is divided into sub regions that work with selective removal of inorganic insulating films beneath bump contact areas, reducing stress concentration and improving the bonding interface between the circuit and the panel.

Through these structural refinements, the display apparatus achieves improved durability, suppression of crack propagation, and enhanced resistance to moisture without compromising thinness or alignment accuracy. The resulting display panel provides higher reliability and a longer operational lifespan, particularly suitable for flexible, foldable, and other mechanically demanding display devices.

Hereinafter, embodiments of the present disclosure will be described in detail with reference to the attached drawings.

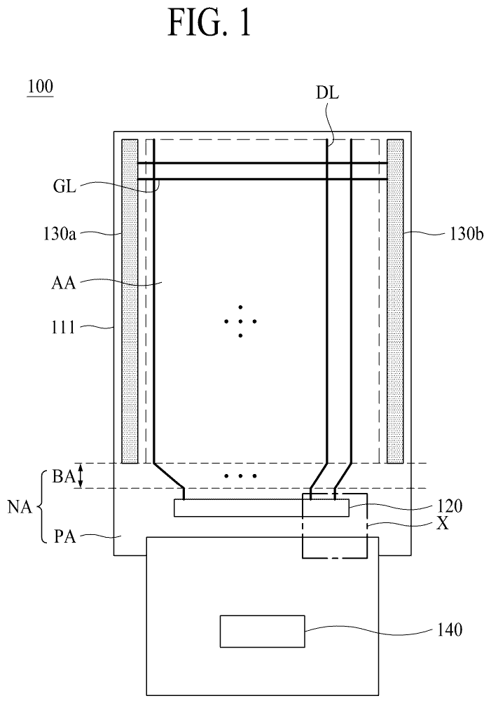

FIG. 1 is an exemplary plan view of a display apparatus 100 according to an embodiment of the present disclosure.

The display panel may include a substrate 111 and a plurality of sub-pixels disposed on the substrate 111.

Referring to FIG. 1, the substrate 111 may include a display area AA and a non-display area NA.

The display area AA may display an image by a plurality of sub-pixels. The display panel may further include a touch sensor array disposed on the display area AA. Each sub-pixel of the display area AA may include a pixel circuit including a plurality of thin film transistors and capacitors, and a light emitting element driven by the pixel circuit. The touch sensor array may be disposed on an encapsulation layer that protects the light emitting element.

The non-display area NA may be located around the display area AA or may surround the display area AA. The non-display area NA may include a bending area BA and a pad area PA. The bending area BA may be located at one side of the display area AA. The pad area PA may be located at one side of the bending area BA. The bending area BA may be an area in which the substrate 111 may be bent. The bending area BA may be disposed between the data driving circuit 120 and the display area AA.

The data driving circuit 120 and the gate driving circuit 130a, 130b may be disposed in the non-display area NA.

The data driving circuit 120 may be disposed in a chip on panel (COP) form on the substrate 111. The data driving circuit 120 may be electrically connected to the display panel through a data line DL.

The gate driving circuit 130a, 130b may be disposed on the substrate 111. The gate driving circuit 130a, 130b may be in the form of a GIP (Gate In Panel) disposed inside the display panel. The gate driving circuit 130a, 130b may be disposed at the left end and right end of the display area AA on the substrate 111, but the embodiment of the present disclosure is not limited thereto.

The gate driving circuit 130a, 130b may be electrically connected to sub-pixels disposed in the display area AA through gate lines GL. A plurality of gate lines GL may be disposed to intersect a plurality of data lines DL, but the embodiment of the present disclosure is not limited thereto.

The display controller 140 may be disposed on a printed circuit board (PCB). The display controller 140 may control the data driving circuit 120 and the gate driving circuit 130a, 130b. The printed circuit board (PCB) may be coupled to one end of the substrate 111.

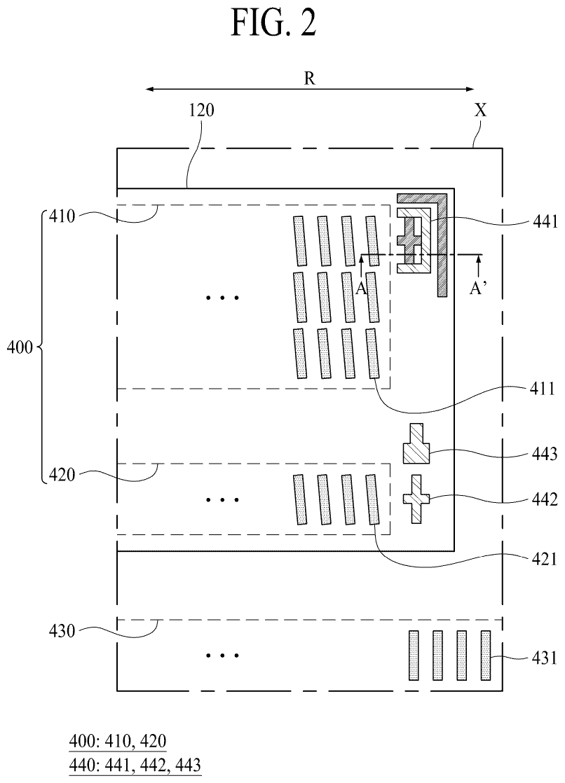

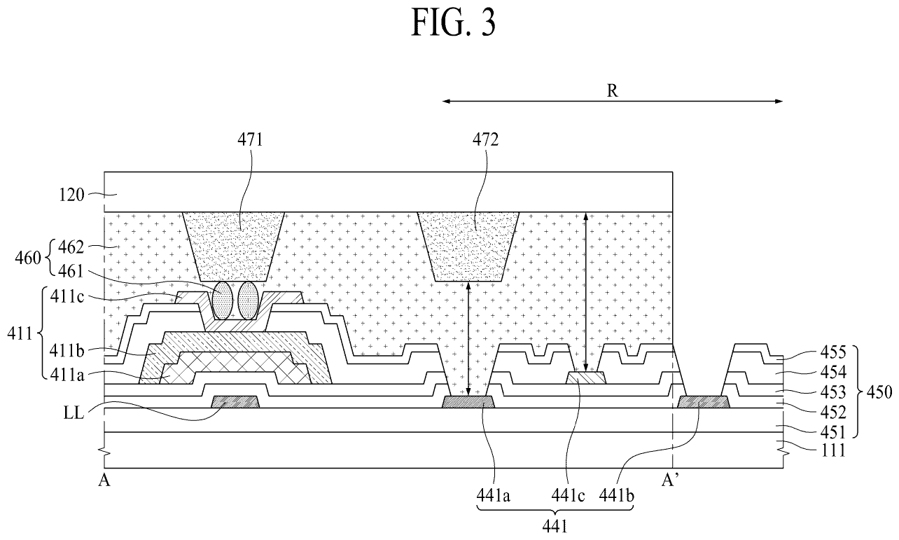

FIG. 2 is an exemplary drawing showing the X area of FIG. 1, and FIG. 3 is an exemplary cross-sectional view along line A-A′ of FIG. 2.

Referring to FIG. 1 and FIG. 2, the pad area PA may include a first pad area 400 disposed in the non-display area NA and to which a data driving circuit 120 is bonded, and a second pad area 430 disposed in the non-display area NA and to which a flexible printed circuit is bonded. The first pad area 400 may be disposed between the display area AA and the second pad area 430. The first pad area 400 may be an area disposed in the non-display area NA and to which the data driving circuit 120 is bonded (or attached). The first pad area 400 may be a driving circuit bonding pad area or a driving circuit attachment area, but the embodiments of the present disclosure are not limited thereto. The second pad area 430 may be an area disposed in the non-display area NA and to which a flexible printed circuit is bonded (or attached). The second pad area 430 may be a film bonding pad area or a film attachment area, but the embodiments of the present disclosure are not limited thereto.

Referring to FIG. 2, the pad area PA may include a first pad area 400 and an alignment mark 440 spaced apart from the first pad area 400. As used herein, pad area and pad region may be used interchangeably unless stated otherwise.

The first pad area 400 may have pad electrodes 411, 421 disposed to input or output signals for driving the display panel. The first pad area 400 may include a 1-1 pad area 410 and a 1-2 pad area 420. The 1-1 pad area 410 may be disposed between the display area AA and the 1-2 pad area 420.

A first pad region may be subdivided into sub-regions to facilitate routing, bonding, and reliability. In particular, a first sub-region (also referred to as the 1-1 pad region 410) and a second sub-region (also referred to as the 1-2 pad region 420) denote respective portions of the first pad region. Each sub-region may include one or more pad electrodes configured to input or output driving signals of the display panel. The sub-regions may be distinguished by location (e.g., the 1-1 pad region 410 disposed between the display area AA and the 1-2 pad region 420), by function (e.g., providing different subsets of data, reference, ground, or test pads), and/or by manufacturing considerations (e.g., selective removal of insulating films or different bump layouts). The labels “1-1” and “1-2” are used for identification only and do not, by themselves, imply any limitation on number, order, geometry, or signal type.

In the 1-1 pad area 410, pad electrodes 411 may be disposed to input or output signals for driving the display panel. In the 1-2 pad area 420, pad electrodes 421 may be disposed to output or input signals for driving the display panel.

The alignment mark 440 may be disposed spaced apart from the first pad area 400 in the row direction R, but the embodiment of the present disclosure is not limited thereto. The alignment mark 440 may be used as an identification mark to identify the position of the data driving circuit 120 in the process of bonding the data driving circuit 120 and the display panel 110 or to align the data driving circuit 120 and the display panel.

The alignment mark 440 may include a first alignment mark 441 and a second alignment mark 442. The first alignment mark 441 may be disposed to be spaced apart from the 1-1 pad area 410. The second alignment mark 442 may be disposed to be spaced apart from the 1-2 pad area 420. The alignment mark 440 may further include a third alignment mark 443 arranged between the first alignment mark 441 and the second alignment mark 442. The third alignment mark 443 may be spaced apart from the 1-1 pad area 410, from the 1-2 pad area 420, or from both.

Referring to FIG. 2, film pad electrodes 431 for inputting and outputting signals for driving the display panel may be disposed in the second pad area 430.

Referring to FIG. 2, a data driving circuit 120 may be included that is bonded (or attached) to a first pad area 400. The data driving circuit 120 may be disposed to overlap the first pad area 400 and the alignment mark 440. The alignment mark 440 may be disposed to be disposed on the inner side of an edge of the data driving circuit 120, but the embodiment of the present disclosure is not limited thereto.

The present disclosure aims to improve COP (Chip on Panel) cracks caused by interference between a driver IC and the panel by reducing the panel thickness at the part where the driver IC edge area and the panel come into contact, thereby minimizing interference.

To this end, the structure of the alignment mark disposed at the edge area of the driver IC is changed to reduce the panel thickness and minimize interference between the driver IC and the panel, and the inorganic insulating film of the TFT that interferes with the bump is removed to minimize interference with the bump.

To explain more specifically, referring to FIG. 2 and FIG. 3, the pad area PA of the display panel may be disposed on the substrate 111. The pad area PA may include an insulating layer 450, pad electrodes 411, 421, and an alignment mark 440.

The insulating layer 450 may be provided with a plurality of insulating layers and may be disposed on the substrate 111. The insulating layer 450 may be a layer formed by including an inorganic material.

The insulating layer 450 may include a first inorganic insulating layer 451, a second inorganic insulating layer 452, a third inorganic insulating layer 453, a fourth inorganic insulating layer 454, and a fifth inorganic insulating layer 455, but the embodiments of the present disclosure are not limited thereto.

The first inorganic insulating layer 451 may be disposed on the substrate 111 as a buffer layer. The second inorganic insulating layer 452 may be disposed on the first inorganic insulating layer 451 as an interlayer insulating layer. The third inorganic insulating layer 453 may be disposed on the second inorganic insulating layer 452 as an interlayer insulating layer. The fourth inorganic insulating layer 454 may be disposed on the third inorganic insulating layer 453 as a buffer layer (touch buffer layer). The fifth inorganic insulating layer 455 may be disposed on the fourth inorganic insulating layer 454 as an interlayer insulating layer (touch interlayer insulating layer).

For example, the first inorganic insulating layer 451 may be a buffer layer, the second inorganic insulating layer 452 may be an interlayer insulating layer, the third inorganic insulating layer 453 may be an interlayer insulating layer, the fourth inorganic insulating layer 454 may be a buffer layer, and the fifth inorganic insulating layer 455 may be an interlayer insulating layer, but the embodiments of the present disclosure are not limited thereto.

Referring to FIG. 2 and FIG. 3, a link line LL, a 1-1 metal layer 441a, and a 1-2 metal layer 441b may be disposed on a first inorganic insulating layer 451. The link line LL may be a line for transmitting a signal. For example, the link line LL may be, but is not limited to, a gate line, a data line, or a reference voltage line. The 1-1 metal layer 441a and the 1-2 metal layer 441b may be metal layers such as a gate electrode or a gate line as part of the first alignment mark 441, but the embodiments of the present disclosure are not limited thereto.

Referring to FIGS. 2 and 3, a pad electrode 411 may be disposed on a substrate 111. The pad electrode 411 may be disposed in a pad area PA of an insulating layer 450. The pad electrode 411 may include at least one metal pattern. The pad electrode 411 may include a plurality of metal patterns. The metal pattern may include at least one metal layer.

The pad electrode 411 may include a first metal layer 411a, a second metal layer 411b, and a third metal layer 411c, but the embodiment of the present disclosure is not limited thereto. The pad electrode 411 may be formed by arranging or stacking a first metal layer 411a, a second metal layer 411b, and a third metal layer 411c.

The first metal layer 411a may be disposed on the third inorganic insulating layer 453. The first metal layer 411a may be disposed to overlap the link line LL. The first metal layer 411a may include a source electrode material and a drain electrode material, but the embodiments of the present disclosure are not limited thereto.

The second metal layer 411b may be disposed on the first metal layer 411a. For example, the second metal layer 411b may be disposed to cover the first metal layer 411a.

The third metal layer 411c may be disposed on the second metal layer 411b. For example, the third metal layer 411c may be made of the same material as the touch electrode of the touch sensor array, but the embodiment of the present disclosure is not limited thereto. The third metal layer 411c may be formed together with the touch electrode when it is formed, but the embodiment of the present disclosure is not limited thereto. The third metal layer 411c may be disposed in an area where a portion of the fourth inorganic insulating layer 454 and the fifth inorganic insulating layer 455 is removed. For example, the third metal layer 411c may be in contact with the second metal layer 411b through a contact hole formed in the fourth inorganic insulating layer 454 and the fifth inorganic insulating layer 455.

Referring to FIG. 2 and FIG. 3, an alignment mark 440 may be disposed on a substrate 111. The alignment mark 440 may include a first alignment mark 441, a second alignment mark 442, and a third alignment mark 443, but the embodiment of the present disclosure is not limited thereto. The cross-sectional structures of the first to third alignment marks 441, 442, 443 may be the same, but the embodiment of the present disclosure is not limited thereto. Hereinafter, the first alignment mark 441 will be described.

The first alignment mark 441 may include a 1-1 metal layer 441a, a 1-2 metal layer 441b, and a second metal layer 441c, but the embodiment of the present disclosure is not limited thereto. The first alignment mark 441 may be formed by arranging or stacking a 1-1 metal layer 441a, a 1-2 metal layer 441b, and a second metal layer 441c.

The 1-1 metal layer 441a and the 1-2 metal layer 441b may be disposed on the first insulating layer 451 like the link line LL. The 1-1 metal layer 441a and the 1-2 metal layer 441b may be made of the same material as the link line LL, but the embodiments of the present disclosure are not limited thereto. The 1-1 metal layer 441a and the 1-2 metal layer 441b may be formed together when the link line LL is formed, but the embodiments of the present disclosure are not limited thereto.

The second metal layer 441c may be disposed on the third inorganic insulating layer 453 like the first metal layer 411a. The second metal layer 441c may include a source electrode material and a drain electrode material, but the embodiments of the present disclosure are not limited thereto.

Referring to FIG. 3, the present disclosure aims to improve COP (Chip on Panel) cracks caused by interference between the driver IC (data driving circuit 120) and the panel. To this end, a structure different from the conventional alignment mark which includes a buffer layer and an interlayer insulating layer on the substrate, and a metal layer and insulating layer formed thereon is adopted. Specifically, the structure includes a first inorganic insulating layer on the substrate; 1-1 metal layer and 1-2 metal layer on the first inorganic insulating layer; and a second metal layer 441c on a third inorganic insulating layer. By forming a metal layer under the bump and then removing the inorganic insulating layer, and by forming another metal layer at the edge region of the driver IC and removing the inorganic insulating layer thereafter, the height of the pad itself may be reduced. As a result, the thickness of the portion of the panel may also be reduced, thereby minimizing interference.

In addition, a metal layer is disposed underneath the removed area of the inorganic insulating layer that directly interferes with the bump, thereby keeping the thickness of the inorganic insulating layer constant and minimizing interference with the bump.

In addition, the structure of the alignment mark disposed at the edge area of the driver IC is changed to reduce the panel thickness, thereby minimizing interference between the driver IC and the panel.

The data driving circuit 120 may be disposed on the insulating layer 450.

The data driving circuit 120 may be a circuit for driving a plurality of data lines DL. The data driving circuit 120 may include a first bump 471 and a second bump 472, but the embodiment of the present disclosure is not limited thereto. The data driving circuit 120 may include a plurality of bumps, but for convenience of explanation, only the first bump 471 and the second bump 472 are illustrated, but the embodiment of the present disclosure is not limited thereto.

The first bump 471 may be a bump for signal transmission. The first bump 471 is electrically connected to the pad electrode 411, and the first bump 471 may supply a signal to the pad electrode 411. The data driving circuit 120 may include at least one first bump 471 electrically connected to the pad electrode 411.

The second bump 472 may not be connected to the pad electrode. The second bump 472 may be a dummy bump, but the embodiments of the present disclosure are not limited thereto.

The data driving circuit 120 may be connected or combined with the insulating layer 450 by a bonding process. The data driving circuit 120 may be attached to the pad area PA of the insulating layer 450 through the adhesive layer 460. For example, the adhesive layer 460 may be disposed between the insulating layer 450 and the data driving circuit 120. The adhesive layer 460 may include a conductive ball 461 and an adhesive 462, but the embodiments of the present disclosure are not limited thereto.

The conductive ball 461 may have a core structure. In addition, the conductive ball 461 may have a core-shell structure including a core and a shell surrounding the core, but the embodiments of the present disclosure are not limited thereto. In the case of a core structure, the core may be made of a metal material including at least one of gold (Au), silver (Ag), nickel (Ni), copper (Cu), lead (Pb), and platinum (Pt), but the embodiments of the present disclosure are not limited thereto. In the case of a core-shell structure, the core may be made of a resin, and the shell may be made of a metal material including at least one of gold (Au), silver (Ag), nickel (Ni), copper (Cu), lead (Pb), and platinum (Pt), but the embodiments of the present disclosure are not limited thereto.

The adhesive 462 may be an acrylic or silicone adhesive, but the embodiments of the present disclosure are not limited thereto. The adhesive 462 may have a conductive ball 461 mixed in it. The conductive ball 461 may be disposed between the pad electrode 411 and the first bump 471 to electrically connect the pad electrode 411 and the data driving circuit 120. The conductive ball 461 may facilitate signal transmission between the data driving circuit 120 and the pad electrode 411.

An embodiment of this disclosure is described as follows.

A display apparatus according to an embodiment of the present disclosure may include a substrate including a display area and a non-display area, a first pad area disposed in the non-display area, and an alignment mark disposed spaced apart from the first pad area.

According to a display apparatus according to an embodiment of the present disclosure, a first pad region includes a 1-1 pad region and a 1-2 pad region, and a pad electrode to which a driving signal of a display panel is input or output may be disposed.

According to the display apparatus according to the embodiment of the present disclosure, the 1-1 pad area may be disposed between the display area and the 1-2 pad area.

According to the display apparatus according to the embodiment of the present disclosure, the alignment mark may include first alignment mark, second alignment mark, and third alignment mark.

According to the display apparatus according to the embodiment of the present disclosure, the alignment marks may be spaced apart from the first pad area in the row direction.

According to the display apparatus according to the embodiment of the present disclosure, the alignment mark may be an identification mark for aligning a data driving circuit and a display panel.

According to the display apparatus according to the embodiment of the present disclosure, the first alignment mark may be spaced apart from the 1-1 pad area.

According to the display apparatus according to the embodiment of the present disclosure, the alignment mark may be disposed on the inner side of the edge of the data driving circuit.

A display apparatus according to an embodiment of the present disclosure includes a substrate including a display area and a non-display area, a plurality of insulating layers disposed on the substrate, a pad electrode disposed on the substrate and including a plurality of metal patterns, and first to third alignment marks disposed on the substrate and adjacent to the pad electrodes, wherein the first alignment mark may include a 1-1 metal layer, a 1-2 metal layer, and a second metal layer.

According to the display apparatus according to the embodiment of the present disclosure, the 1-1 metal layer and the 1-2 metal layer may be disposed on a first insulating layer of the plurality of insulating layers, and the second metal layer may be disposed on a third insulating layer of the plurality of insulating layers.

The exemplary embodiments of the present disclosure can further be described as follows.

A display apparatus may include a substrate 111 including a display area AA and a non-display area NA, a plurality of insulating layers 450 disposed on the substrate 111, a pad region located in the non-display area NA and including a plurality of stacked metal patterns 411, and an alignment mark disposed in the non-display area NA and spaced apart from the pad region. The plurality of insulating layers may include a first insulating layer 451, a second insulating layer 452, and a third insulating layer 453. The alignment mark may comprise a first metal layer 441a and a second metal layer 441b disposed on the first insulating layer 451, and a third metal layer 441c disposed on the third insulating layer 453. In other words, the third metal layer 441c may be disposed on a layer at a different plane relative to a layer on which the first metal layer 441a and the second metal layer 441b are disposed. The second insulating layer 452 may be positioned above the first insulating layer 451.

A pad electrode 411 may be disposed in the pad region. The pad region may include a first pad region 410 and a second pad region 420. The pad electrode may be configured for inputting or outputting driving signals of a display panel. The first pad region 410 may be disposed between the display area AA and the second pad region 420.

The alignment mark may include a first alignment mark 441, a second alignment mark 442, and a third alignment mark 443. The first alignment mark 441 may be spaced apart from the first pad region 410. The alignment mark may be spaced apart from the pad region in the row direction R. The third alignment mark may be an identification mark for aligning a data driving circuit 120 and a display panel. The alignment mark may be disposed at the inner edge of a data driving circuit 120.

The first metal layer 441a, the second metal layer 441b, and a link line LL may be disposed on one insulating layer 451 of the plurality of insulating layers 450. The link line LL may be configured to transmit a signal. The first metal layer 441a, the second metal layer 441b, and the link line LL may be formed of the same material. The third metal layer 441c may be positioned between the first metal layer 441a and the second metal layer 441b in a plan view.

According to the embodiments of the present disclosure described above, a display apparatus with improved reliability may be provided.

According to an embodiment of the present disclosure, a display apparatus may be provided that includes a first alignment mark in which a 1-1 metal layer and a 1-2 metal layer are disposed on a first insulating layer, and a second metal layer is disposed on a third insulating layer, thereby preventing the occurrence or propagation of cracks in the display panel.

According to an embodiment of the present disclosure, a display apparatus with improved moisture permeability may be provided by preventing cracks from occurring or propagating in a display panel.

According to an embodiment of the present disclosure, a display apparatus may be provided that may prevent various types of wire from being damaged by preventing cracks from occurring or propagating in a display panel.

According to an embodiment of the present disclosure, a display apparatus capable of low power consumption may be provided by preventing cracks from occurring or propagating in a display panel, thereby improving the lifespan of the display apparatus.

According to an embodiment of the present disclosure, the display apparatus with improved reliability may be provided.

According to an embodiment of the present disclosure, the display apparatus may include the first alignment mark in which the 1-1 metal layer and the 1-2 metal layer are disposed on the first insulating layer, and a second metal layer is disposed on a third insulating layer, thereby preventing the occurrence or propagation of cracks in the display panel.

According to an embodiment of the present disclosure, by preventing the occurrence or propagation of cracks in the display panel, the display apparatus with improved moisture resistance may be provided.

According to an embodiment of the present disclosure, by preventing the occurrence or propagation of cracks in the display panel, damage to various wires may be avoided.

According to an embodiment of the present disclosure, by preventing the occurrence or propagation of cracks in the display panel and thereby improving the lifespan of the display apparatus, a display apparatus capable of low power consumption can be provided.

The display apparatus according to various embodiments of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle navigation system, a vehicle display apparatus, a vehicle device, a theater device, a theater display apparatus, a television, a wallpaper device, a signage device, a game device, a notebook, a monitor, a camera, a camcorder, and home appliances.

The above description is merely an example of the technical idea of this disclosure, and those with ordinary skill in the art to which this disclosure pertains may make various modifications and variations without departing from the essential characteristics of this disclosure. In addition, the embodiments disclosed in this disclosure are not intended to limit the technical idea of this disclosure but rather to explain it, and therefore the scope of the technical idea of this disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a display area and a non-display area;
a first pad region disposed in the non-display area; and
an alignment mark spaced apart from the first pad region.

2. The display apparatus of claim 1, further comprising a pad electrode disposed in the first pad region,
wherein the first pad region includes a 1-1 pad region and a 1-2 pad region, and
wherein the pad electrode is configured to input or output driving signals of a display panel.

3. The display apparatus of claim 2, wherein the 1-1 pad region is disposed between the display area and the 1-2 pad region.

4. The display apparatus of claim 3, wherein the alignment mark includes a first alignment mark, a second alignment mark, and a third alignment mark.

5. The display apparatus of claim 4, wherein the alignment mark is spaced apart from the first pad region in a row direction.

6. The display apparatus of claim 1, wherein the alignment mark is an identification mark for aligning a data driving circuit and a display panel.

7. The display apparatus of claim 4, wherein the first pad region includes a 1-1 pad region and a 1-2 pad region, and
wherein the first alignment mark is spaced apart from the 1-1 pad region.

8. The display apparatus of claim 1, wherein the alignment mark is disposed at an inner edge of a data driving circuit.

9. A display apparatus comprising:
a substrate including a display area and a non-display area;
a plurality of insulating layers disposed on the substrate;
a pad electrode disposed on the substrate, the pad electrode including a plurality of metal patterns; and
first, second, and third alignment marks disposed on the substrate and adjacent to the pad electrode,
wherein the first alignment mark includes a 1-1 metal layer, a 1-2 metal layer, and a second metal layer.

10. The display apparatus of claim 9, wherein the 1-1 metal layer and the 1-2 metal layer are disposed on a first insulating layer of the plurality of insulating layers, and
wherein the second metal layer is disposed on a third insulating layer of the plurality of insulating layers.

11. A display apparatus comprising: a substrate including a display area and a non-display area;
a plurality of insulating layers disposed on the substrate, the plurality of insulating layers including a first insulating layer, a second insulating layer, and a third insulating layer;
a pad region located in the non-display area and including a plurality of stacked metal patterns; and
an alignment mark disposed in the non-display area and spaced apart from the pad region,
wherein the alignment mark comprises a first metal layer and a second metal layer disposed on the first insulating layer, and a third metal layer disposed on the third insulating layer, and
wherein the second insulating layer is positioned above the first insulating layer.

12. The display apparatus of claim 11, further comprising a pad electrode disposed in the pad region,
wherein the pad region includes a first pad region and a second pad region, and
wherein the pad electrode is configured to input or output driving signals of a display panel.

13. The display apparatus of claim 12, wherein the first pad region is disposed between the display area and the second pad region.

14. The display apparatus of claim 11, wherein the alignment mark includes a first alignment mark, a second alignment mark, and a third alignment mark.

15. The display apparatus of claim 14, wherein the first pad region includes a 1-1 pad region and a 1-2 pad region, and
wherein the first alignment mark is spaced apart from the 1-1 pad region.

16. The display apparatus of claim 11, wherein the alignment mark is spaced apart from the pad region in the row direction.

17. The display apparatus of claim 11, wherein the alignment mark is an identification mark for aligning a data driving circuit and a display panel.

18. The display apparatus of claim 11, wherein the alignment mark is disposed at the inner edge of a data driving circuit.

19. The display apparatus of claim 11, further comprising a link line configured to transmit a signal, wherein the first metal layer, the second metal layer, and the link line are disposed on one insulating layer of the plurality of insulating layers.

20. The display apparatus of claim 19, wherein the first metal layer, the second metal layer, and the link line are formed of the same material.

21. The display apparatus of claim 11, wherein the third metal layer is positioned between the first metal layer and the second metal layer in a plan view.
